(19) United States
(12) Patent Application Publication
(10) Pub. No.: US 2022/0369455 A1
(43) Pub. Date: Nov. 17, 2022

(54) ELECTRICAL CONNECTION PAD WITH ENHANCED SOLDERABILITY AND CORRESPONDING METHOD FOR LASER TREATING AN ELECTRICAL CONNECTION PAD

(71) Applicant: TECHNISCHE HOCHSCHULE ASCHAFFENBURG, Aschaffenburg (DE)

(72) Inventors: Stefan Rung, Weibersbrunn (DE); Ralf Hellmann, Aschaffenburg (DE)

(21) Appl. No.: 17/628,260

(22) PCT Filed: Jul. 22, 2019
(86) PCT No.: PCT/EP2019/069697

§ 371 Date: Jan. 19, 2022

(51) Int. Cl. H05K 1/11; H01L 23/00; H05K 3/40

(52) U.S. Cl. CPC H05K 1/111; H01L 24/81; H05K 3/4007; H01L 2224/81385; H01L 2224/81022; H01L 2224/81447; H01L 2224/81418; H01L 2224/81411; H01L 2224/81416; H01L 2224/81469; H01L 2224/81444; H01L 2224/81439; H01L 2224/81424; H05K 2203/107

(57) ABSTRACT

The invention concerns an electrical connection pad (10′) for providing an electrical connection between components of an electronic system, wherein the electrical connection pad comprises: a metallic layer (12); and a laser induced periodic surface structure (20), LIPSS, formed on an external surface (16) of the electrical connection pad (10) and exposing the metallic layer (12) and a method for correspondingly laser-treating an electrical connection pad (10).

### FIELD OF THE INVENTION

The present invention is in the field of electrical connection pads for electronic components. In particular, the invention refers to an electrical connection pad with enhanced solderability and to a corresponding method for laser treating an electrical connection pad.

### BACKGROUND OF THE INVENTION

Electrical connection pads, for example metallic solder pads, are typically used for manufacturing electronic devices, like circuit boards, integrated circuits, microchips and the like, for forming electrical connections between different electronic components, such as conductive wirings, passive components or active components. When exposed to an ambient atmosphere, oxidation of such electrical connection pads is a naturally occurring phenomenon. As a result, electrical connection pads, after being transported or stored for some time, can be covered by a layer of metal oxide, which leads to a gradual degradation of the solderability of the electrical connection pads, which in some occasions are no longer usable and must be disposed of.

In view of this, some manufacturing processes of electronic components include the formation of protective layers, like layers of noble metals such as silver or gold, which cover the electrical connection pads during transportation or storage in order to avoid exposure to an ambient atmosphere and hence the formation of oxide layers. However, the additional material required for the protective layer increases the production costs and requires dedicated steps and equipment in a manufacturing process for removing the protective layers before further processing of the electrical connection pads for the formation of electrical connections in an electronic device.

Further, efforts are continuously made in the industry for improving the solderability of electrical connection pads, since it plays a central role in the durability and performance of the resulting electronic devices.

Therefore, there is room for technical improvement regarding the solderability of electrical connection pads and their manufacturing.

### SUMMARY OF THE INVENTION

The present invention addresses the problem of providing electrical connection pads with improved durability and solderability and a method for laser-treating an electrical connection pad allowing to efficiently provide such an electrical connection pad. This problem is solved by an electrical connection pad according to claim 1 and a method according to claim 12. Preferred embodiments of the invention are defined in the appended dependent claims.

A first aspect of the invention relates to an electrical connection pad for providing an electrical connection between electronic components. Such an electrical connection pad may be used for providing an electrical connection in any kind of electronic system, such as circuit boards, integrated circuits, microchips and the like to provide an electrical connection between any two electronic components, such as passive electronic components, active electronic components or conductive wirings. For instance, an electrical connection pad according to the invention may be used to provide an electrical connection between an active device and a passive device within an integrated circuit, or between a passive or an active device and a conductive wiring on a circuit board, or between two conductive wirings.

The electrical connection pad of the invention comprises a metallic layer and a laser induced periodic surface structure formed on an external surface of the electrical connection pad and exposing the metallic layer. “Laser induced periodic surface structure” or in short “LIPSS” refers herein to a periodic pattern that can be induced on the surface of a material if properly treated with pulsed laser light, in particular polarised pulsed laser light, as will be explained further below. The metallic layer is exposed through and by the LIPSS, such that the profile of the metallic layer on the external surface of the electrical connection pad corresponds to the profile of the LIPSS. The profile of the LIPSS defines a periodically varying thickness profile of the electrical connection pad and/or of the metallic layer, which may for instance substantially correspond to a wave profile, wherein the thickness of the electrical connection pad and/or of the metallic layer takes a maximum value at the upper peaks of the wave profile and a minimum value at the lower peaks of the wave profile. The wave profile may for example approximately correspond to a sinusoidal wave profile, although deviations from a perfectly periodic structure may occur.

In particular, the electrical connection pad of the invention may be a solder pad configured for creating a mechanically stable electrical connection between electronic components by soldering, i.e. by transitioning at least in part to a liquid state upon being provided with thermal energy for creating the electrical connection and by transitioning back to solid state after the electrical connection is created, for example after the two electronic components to be connected by the electrical connection, for instance to conductive wirings, are fixed or placed in contact to the electrical connection pad, possibly after the provision of thermal energy has been stopped or reduced.

However, the electrical connection pad of the invention may provide an electrical connection between electronic components by other means, such as gluing, in particular gluing with a conductive glue, welding or bonding.

When the electrical connection pad is used for creating an electrical connection between two electronic components by contact of the electronic components with the metallic layer of the electrical connection pad at the external surface, the surface of the metallic layer available for the electrical connection is defined by the profile of the LIPSS. Thus, due to the LIPSS, the overall surface available for creating an electrical connection is greater than the planar surface that would be available on the same electrical connection pad without the LIPSS. Consequently, the ability of the electrical connection pad to create a durable and stable electrical connection, which may also be referred to as solderability or wettability, is improved with respect to conventional electrical connection pads. Notably, the use of the terms “solderability” and “wettability” herein is not restricted to electrical connection pads that are solder pads only.

The LIPSS can be formed by a laser treatment by which the external surface of the electrical connection pad is laser-treated with a pulsed laser light, in particular a polarised ultrashort-pulse laser light. If the parameters of the laser treatment, in particular the pulse length, the wavelength and the fluence, are properly chosen, the dimensions of the LIPSS can be adapted to the dimensions of the metallic layer and/or to the dimensions of a dielectric layer that may cover the metallic layer after the electrical connection pad has been exposed to an ambient atmosphere for some time, for instance during storage or transportation. Such dielectric layer may for example be a metal oxide layer formed by oxidation of a part of the metallic layer adjacent to the external surface. Since the laser treatment for the formation of the LIPSS allows very finely adjusting the ablation depth, i.e. the amount of ablated material or the depth up to which material is ablated, the electrical connection pads of the invention can be considerably thinner than conventional pads and still display excellent solderability.

The electrical connection pad of the invention can be prepared for its use for forming an electrical connection by a laser treatment, which may allow omitting the formation of a protective layer on the metallic layer. Irrespectively of whether a dielectric layer is formed over the metallic layer, the electrical connection pad can provide an improved solderability due to the LIPSS. Further, if a dielectric layer is formed over the metallic layer, the laser treatment can result in a precise total or partial ablation of the dielectric layer, such that the metallic layer be exposed at the external surface of the electrical connection pad, thereby improving the electrical properties of the electrical connection to be formed. In other words, a proper laser treatment for forming the LIPSS may result in an improved solderability by chemical activation of the electrical connection pad, i.e. exposure of the metallic layer, and by topographic modulation of the external surface, i.e. effective increase in the surface available for establishing an electrical connection.

According to preferred embodiments, the LIPSS may have a period from 100 nm to 10 μm, preferably from 150 nm to 5 μm, more preferably from 200 nm to 1 μm. The “period” of the LIPSS is understood herein as the average distance between two consecutive maxima of the LIPSS external surface. Such maxima may correspond to points of the external surface at which the electrical connection pad and/or the metallic layer has a local maximum of thickness or a local maximum of height over a bottom surface of the electrical connection pad located opposite to the external surface.

The laser treatment may comprise laser ablation and may result both in the formation of the LIPSS and in the removal of at least a part of the metallic layer and/or of a dielectric layer arranged on the metallic layer. When configured for the formation of the LIPSS, the laser treatment may further result in the ablation of material, of the metallic layer and/or of the dielectric layer, for an adjustable “ablation depth”, i.e. an adjustable thickness of the ablated material with respect to the location of the external surface before the laser treatment. The amplitude of the periodic thickness variations of the metallic layer and/or the dielectric layer after the formation of the LIPSS, i.e. the vertical distance between a point of the external surface at which the thickness of the electrical connection pad is maximal and a point of the external surface at which the thickness of the electrical connection pad is minimal, which shall be referred to herein as “modulation amplitude”, may be adjusted by a corresponding configuration of the laser treatment, as will be explained in more detail below. This allows leaser-treating relatively thin electrical connection pads, for example electrical connection pads having the dimensions specified below.

In preferred embodiments, the LIPSS may have a modulation amplitude from 10 nm to 100 μm, preferably from 20 nm to 800 nm, more preferably from 50 nm to 400 nm. Modulation amplitudes within these ranges allow for the formation of the LIPSS and for the corresponding solderability enhancement even in metal layers having thicknesses in the μm-range or below.

According to preferred embodiments of the invention, the metal layer may, after the formation of the LIPSS, have a thickness from 1 μm to 10 mm, preferably from 3 μm to 100 μm, more preferably from 10 μm to 60 μm.

In some preferred embodiments, the metal layer may comprise copper, zinc, tin, lead, brass, platinum, gold, silver and/or aluminium, as well as combinations, compounds and/or alloys thereof.

In some embodiments, the electrical connection pad may further comprise a dielectric layer arranged on the metallic layer, wherein the LIPSS may be further formed in the dielectric layer. If the laser treatment results in a partial removal of the dielectric layer, the LIPSS may hence expose both parts of the metallic layer and parts of the dielectric layer. In other words, the external surface of the electrical connection pad may correspond in part to the metallic layer, for example in regions in which the laser treatment results in a complete removal of the dielectric layer (e.g. the “valley regions” of a LIPSS having an approximate sinusoidal wave profile), and may in part correspond to the dielectric layer that remains on the metallic layer after the laser treatment, for example in regions in which the laser treatment results in no removal or in a partial removal of the dielectric layer (e.g. the “hill regions” of a LIPSS having a sinusoidal wave profile).

The dielectric layer may in some embodiments comprise a metal oxide. As previously mentioned, such a metal oxide layer may form over the metallic layer as a result of oxidation when the electrical connection pad is exposed to the atmosphere for some time, for instance during storage or transportation. Additionally or alternatively, the dielectric layer may comprise other passivation materials such as carbon and/or an organic material. In some embodiments, the dielectric layer may be a metal oxide layer, a carbon layer and/or an organic material layer.

In some preferred embodiments, the dielectric layer may be a metal oxide layer comprising oxide of copper, zinc, tin, lead, brass, platinum, gold, silver and/or of aluminium.

The dielectric layer may have, after the formation of the LIPSS, a thickness between 1 nm and 5 μm, preferably between 1 nm and 1 μm, more preferably between 5 nm and 30 nm. This thickness may correspond to an average maximal thickness of peaks of the dielectric layer remaining on the metallic layer after the laser treatment averaged over all peaks. It will be understood by any person skilled in the art that even accurate laser treatments may result in periodic surface structures having some degree of inhomogeneity or irregularity, including a variable thickness of the metallic layer and/or dielectric layer within a given tolerance.

A further aspect of the invention refers to a circuit board, such as a printed circuit board, comprising an electrical connection pad according to any of the aspects or embodiments of the invention previously described.

A further aspect of the invention refers to a method for laser-treating an electrical connection pad in order to create a laser induced periodic surface structure such as to produce an electrical connection pad according to any of the aspects or embodiments of the invention described above. Creating such electrical connection pad may comprise reconditioning or activating for use an electrical connection pad that has been stored or transported for some time. The electrical connection pad to be laser-treated may comprise a metallic layer and a dielectric layer arranged on the metallic layer and forming an external surface of the electrical connection pad. The method of the invention comprises laser-treating the external surface with a pulsed laser light, thereby forming a LIPSS exposing the metal layer.

The method of the invention can hence be applied to an electrical connection pad after it has been exposed to the atmosphere for some time resulting in the formation of a dielectric layer on the metallic layer, for example a metal oxide layer due to oxidation. Thereby, the dielectric layer can be removed by laser ablation at least in part such that the underlying metallic layer is at least partially exposed again at the exterior surface and the LIPSS can be formed at the exterior surface to enhance the solderability of the electrical connection pad.

In preferred embodiments of the invention, the laser light is ultrashort-pulse laser light. Additionally or alternatively, the laser light may be polarised laser light. Thus, the laser light may in particular be polarised ultrashort-pulse laser light. “Ultrashort-pulse laser light” refers herein to laser light with ultrashort-pulses of light, in particular in the femtosecond or picosecond range but also the short pulses of light, in particular in the nanosecond range. In some embodiments, a solid state laser or a gas laser, for example a Ti-sapphire laser or an Nd:YAG-laser, may be used for generating the laser light for forming the LIPSS.

If the laser light is polarised laser light, the polarization of the laser light may for example be a linear polarization or a circular polarization. Using linearly polarised laser light may result in the formation of a correspondingly oriented LIPSS. Points of the external surface having a given thickness value may be aligned perpendicular to the polarization direction of the laser light, for example when the fluence of the laser light is high, for example above 0.1 J/cm², and may be aligned parallel to the polarization direction of the laser light when the fluence of the laser light is low, for example below 0.1 J/cm². Further, the directionality of the LIPSS can be influenced through an incidence angle of the laser light and/or through an initial surface roughness of the external surface. Thus, differently oriented LIPSS may be combinedly formed on an electrical connection pad by means of respective laser treatments with corresponding polarizations and/or fluences and/or through corresponding initial surface roughness. For example, a first laser treatment with a first linear polarization and a subsequent second laser treatment with a second linear polarization in a direction different to the polarization direction of the first linear polarization, for instance perpendicular thereto, can result in the formation of two different overlapped LIPSS, for instance two mutually perpendicular LIPSS. A similar pattern may be achieved using one polarization direction and two different fluences.

According to preferred embodiments of the invention, the external surface may be laser-treated with laser light pulses having a pulse length from 30 fs to 100 ns, preferably from 100 fs to 40 ps, more preferably from 190 fs to 15 ps. “Pulse length” refers herein to a time interval between a time at which the amplitude of the pulse reaches a specified fraction of its maximal amplitude and a time at which the pulse amplitude drops to the same fraction.

In preferred embodiments, the external surface may be laser-treated with laser light pulses having a wavelength from 193 nm to 10.6 μm, preferably from 343 nm to 1070 nm, more preferably from 1028 nm to 1070 nm.

The laser light may further have a fluence from 0.01 J/cm² to 10 J/cm², preferably from 0.1 J/cm² to 5 J/cm², more preferably from 0.1 J/cm² to 1 J/cm². “Fluence” refers herein to the energy of the laser light that is applied to the external surface of the electrical connection pad per laser spot unit surface, for example per laser spot surface as defined by the 1/e² diameter.

When adjusted according to the parameters as previously specified herein, the laser treatment may result in the formation of the LIPSS having a modulation amplitude from 10 nm to 100 μm, preferably from 20 nm to 800 nm, more preferably from 50 nm to 400 nm. This allows laser treating relatively thin electrical connection pads, for example electrical connection pads having the dimensions specified above, without the risk of damaging or completely destroying the metal layer during the laser treatment.

The laser treatment may result in the formation of the LIPSS having a period from 100 nm to 10 μm, preferably from 150 nm to 5 μm, more preferably from 200 nm to 1 μm. Notably, since the period of the resulting LIPSS may correspond to wavelengths in the visible part of the spectrum, the presence of such a LIPSS on an electrical connection pad formed as a result of the method according to the invention can be revealed by an optical diffraction pattern detectable by illuminating the electrical connection pad with visible light. The light reflected from the electrical connection pad may be differently reflected for different wavelengths due to the presence of the LIPSS, thereby giving rise to a coloured reflection pattern or hologram, which may be even perceivable by naked eye.

According to preferred embodiments of the invention, laser-treating the external surface may comprise laser-treating the external surface completely or laser-treating from 10% to 90%, preferably form 30% to 80%, more preferably from 50% to 70% of the external surface. For laser-treating the external surface, laser light with a given spot size may be used to scan the external surface over a first direction at different positions in a second direction. The second direction may preferably be perpendicular to the first direction. Completely laser-treating the external surface may comprise linearly scanning the external surface with the laser light over the first direction at said different positions, wherein the different positions may be mutually spaced apart in the second direction by a distance equal to or smaller than the spot size.

Partly laser-treating the external surface, for example laser-treating 10% to 90% of the external surface, may comprise linearly scanning the external surface with the laser light over the first direction at said different positions, wherein the different positions may be mutually spaced apart in the second direction by a distance greater than the spot size. The spot size, as defined for example by the 1/e²-diameter, may be from 1 μm to 1 mm, preferably from 10 μm to 150 μm.

The present inventors found out that in order to achieve the desired enhancement of the solderability of the electrical connection pad, it may not be necessary to laser-treat the entire external surface. Instead, it might be sufficient to laser-treat only a part of the external surface and still achieve an improvement in the solderability of the electrical connection pad with respect to electrical connection pads having no LIPSS.

In preferred embodiments of the invention, laser-treating the external surface may comprise scanning at least a part of the external surface with the laser light using a laser light deflection system. The use of a laser light deflection system may allow laser-treating the external surface by correspondingly moving the laser light deflection system to scan the entire external surface or parts thereof. The laser light deflection system may comprise one of more of a polariser, a beam splitter, a focal lens, a deflector and an optical filter. The laser light deflection system may for example comprise a movable and/or rotatable mirror-device, such as a galvanometer scanner, and a focusing length or a movable processing head, such as a flying optic device. However, other configurations of the laser light deflection system allowing for a relative movement between the laser light and the external surface of the electrical connection pad are also possible.

According to preferred embodiments of the invention, the laser light may be configured such that a modulation amplitude of the LIPSS may be, after the laser treatment, equal to or greater than a thickness of the dielectric layer (as defined before the laser treatment). The laser treatment may hence result in at least a partial reduction of the thickness of the dielectric layer. Additionally or alternatively, the laser treatment may also result in at least a partial reduction of the thickness of the metallic layer.

In some embodiments, laser-treating the external surface may comprise completely removing the dielectric layer. In other embodiments, laser-treating the external surface may comprise partially removing the dielectric layer. Remnants of the dielectric layer may remain on the metallic layer after the dielectric layer is partially removed. Advantageously, partially removing the dielectric layer, such that after the laser treatment, a part of the dielectric layer remains on the metallic layer, allows using the remaining part of the dielectric layer as a solder stopper, thereby rendering the application or use of an additional solder stopper layer or solder stopper elements unnecessary for performing a soldering operation with the electrical connection pad.

“Configuring the laser light” may in particular imply adjusting the settings of the corresponding laser device in order to achieve predefined values of the wavelength, the pulse length and/or the fluence of the generated laser light. For example, the amount of ablation provided by the laser treatment, i.e. the amount of dielectric layer and/or metallic layer that is removed as a consequence of the laser treatment, may be selected by correspondingly adjusting the fluence of the laser light and the amount of pulses of laser light used for forming the LIPSS. The modulation amplitude of the LIPSS may be selected by correspondingly adjusting the wavelength of the laser light. In particular, the modulation amplitude may correspond to up to ⅓ of the wavelength of the laser light, wherein the modulation amplitude may be selected by correspondingly configuring, for example, the fluence of the laser light and the number of pulses of laser light used for forming the LIPSS. The period of the LIPSS may be selected by correspondingly adjusting the wavelength of the laser light. For example, using laser light with a wavelength from 1028 nm to 1070 nm may lead to the formation of a LIPSS with a period from 850 nm to 1 μm and a modulation amplitude from 50 nm to 360 nm.

The LIPPS is formed on the external surface of the electrical connection pad as a result of the laser treatment. According to the current physical theories for LIPSS formation, the laser light creates an electromagnetic wave on said external surface that propagates along said external surface. As an intra-pulse effect, the electromagnetic wave propagating on said external surface generates an interference pattern on said external surface leading to a periodically modulated intensity. This periodically modulated intensity causes a correspondingly periodically modulated material ablation and/or a thermal instability, thereby forming the LIPSS on said external surface.

The external surface may be laser-treated with an incidence angle from 0° to 45°, preferably from 0° to 22.5°. “Incidence angle” refers herein to an angle defined between a direction perpendicular to the plane of the external surface of the electrical connection pad and the direction in which the laser light used for forming the LIPSS propagates. The incidence angle may for example be 0°, such that the laser light is incident on the external surface perpendicularly.

### BRIEF DESCRIPTION OF THE FIGURES

FIG. 1 shows an electrical connection pad before undergoing laser treatment according to an embodiment of the invention.

FIG. 2 illustrates the laser treatment of an electrical connection pad with a laser light at a given incidence angle according to an embodiment of the invention.

FIG. 3 illustrates the laser treatment of an electrical connection pad with a laser light at a given incidence angle according to an embodiment of the invention using a laser light deflection system.

FIG. 4 shows an electrical connection pad with a LIPSS according to an embodiment of the invention.

FIG. 5 shows an electrical connection pad with a LIPSS according to another embodiment of the invention.

FIG. 6 shows the height profile of a LIPSS according to embodiments of the invention.

FIG. 7 shows a circuit board incorporating an electrical connection pad with a LIPSS according to an embodiment of the invention.

FIG. 8 shows top views of electrical connection pads according to embodiments of the invention.

### DETAILED DESCRIPTION OF PREFERRED EMBODIMENTS

For the purposes of promoting an understanding of the principles of the invention, reference will now be made to preferred embodiments illustrated in the drawings, and specific language will be used to describe the same. It will nevertheless be understood that no limitation of the scope of the invention is thereby intended, alterations and further modifications in the illustrated devices and such further applications of the principles of the invention as illustrated therein being contemplated as would normally occur now or in the future to one skilled in the art to which the invention relates.

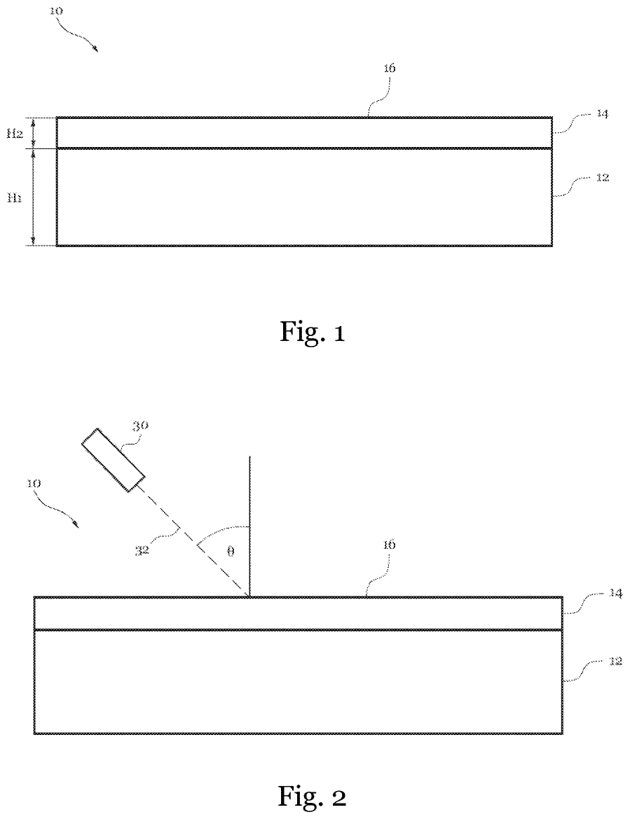

FIGS. 1 to 3 illustrate a method for laser treating an electrical connection pad 10 comprising a metallic layer 12 and a dielectric layer 14, wherein the dielectric layer 14 is arranged on top of the metallic layer 12 forming an external surface 16 of the connection pad 10. In the embodiment shown, the dielectric layer 14 is a metal dielectric layer. Before the laser treatment, the dielectric layer 14 has, in the example shown, a thickness H2 of about 30 nm. The metallic layer 12 has, in the example shown, a thickness H1 i of about 30 μm. In the embodiment shown, the metallic layer 12 comprises copper, and the dielectric layer 14 comprises copper oxide formed as a consequence of the electrical connection pad 10 being exposed to the atmosphere for some time. Thus, before the laser treatment, the upper surface of the dielectric layer 14 forms the external surface 16 of the electrical connection pad 10.

The method of the invention comprises laser-treating the external surface 16 with a pulsed laser light 32 generated by a laser device 30. In the example shown, the laser device 30 is an ultrashort solid state laser device, for example a Ytterbium-doped fiber laser, configured to generate linearly polarised ultrashort-pulse laser light having a pulse length of about 200 fs, a wavelength of about 1030 nm and a fluence of about 0.5 J/cm². However, any other values within the previously described ranges are possible within the context of the present invention.

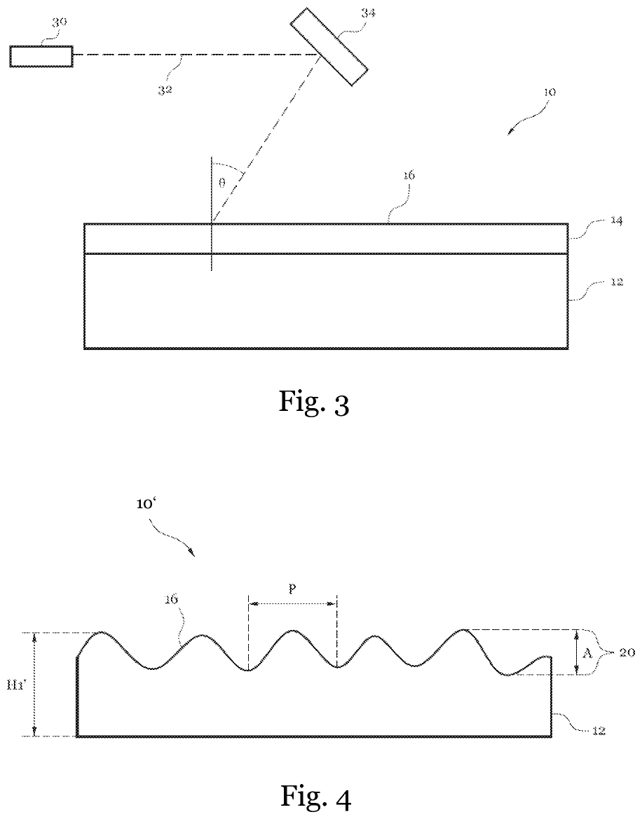

As shown in FIG. 2, the external surface 16 can be laser-treated with an incidence angle θ, i.e. an angle between the incidence direction of the laser light 32 and a direction perpendicular to the plane of the external surface 16, with the incidence angle θ being in the range of 0° to 45°, for example being around 45°, as shown in FIG. 2. As shown in FIG. 3, a laser light deflection system 34 can be used for scanning the laser light 32 throughout the external surface 16 or a part thereof, for example using a rotatable mirror or the like.

As a result of the laser treatment with the indicated parameters, an electrical connection pad 10′ with an enhanced solderability comprising a LIPSS 20 on the external surface 16 is formed.

FIG. 4 shows an example in which, before the laser treatment, the dielectric layer 14 had a thickness of about 3 nm and the metallic layer 12 had a thickness of 30 μm. Laser light with a fluence of 0.1 J/cm², a wavelength of about 1030 nm, and a pulse length of 200 fs was used for forming the LIPSS 20. As a result of the laser treatment, the dielectric layer 14 is completely ablated or removed, such that the electrical connection pad 10′ no longer comprises, after the laser treatment, the dielectric layer 14. In this case, the LIPSS 20 is entirely formed in the metallic layer 12, which also forms the external surface 16. As a result of the laser treatment, the metallic layer 12 now has a thickness H1′ that can be equal to or smaller than the thickness H1 of the metallic layer 12 before the laser treatment, depending on the particular settings of the laser treatment. In the example shown, the (maximal) thickness H1′ of the metallic layer 12 after the laser treatment is about 30 μm. The LIPSS 20 has an amplitude modulation A and a period P. In the example shown in FIG. 4, the amplitude modulation is about 300 nm and the period is about 900 nm.

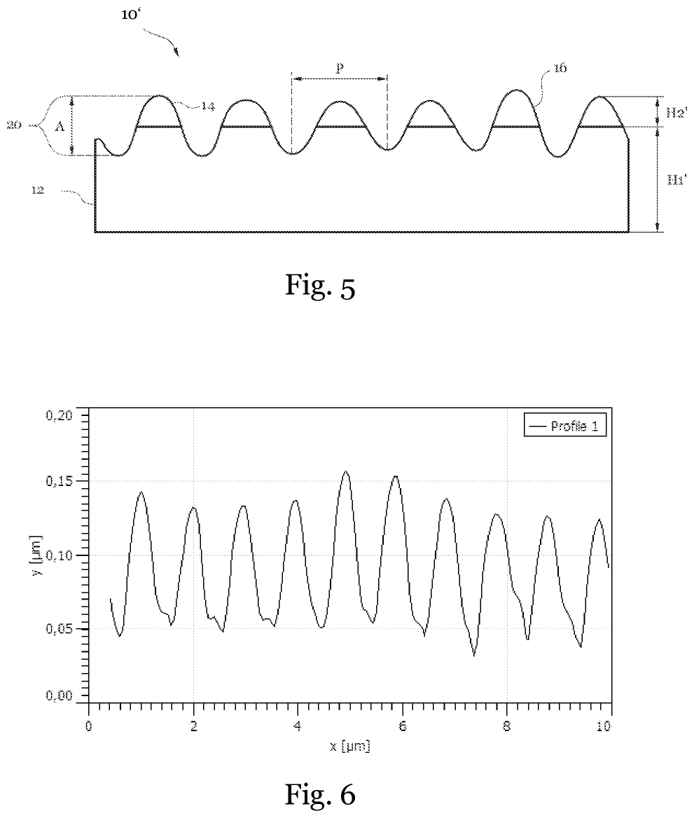

FIG. 5 shows an example in which, before the laser treatment, the dielectric layer 14 had a thickness of 30 nm and the metallic layer 12 had a thickness of 30 μm. Laser light with a fluence of 0.1 J/cm², a wavelength of 1030 nm, and a pulse length of 200 fs was used for forming the LIPSS 20. As a result of the laser treatment, the dielectric layer 14 is only partly ablated or removed, such that the electrical connection pad 10′ comprises, after the laser treatment, a remnant of the dielectric layer 14 formed on top of the metallic layer 12. In this case, the LIPSS 20 is formed in the metallic layer 12 and the dielectric layer 14, which form in combination the external surface 16. The profile of the LIPSS 20 substantially corresponds to an approximate sinusoidal wave profile. The thickness of the electrical connection pad 10′ takes maximal values at the upper peaks of the sinusoidal wave profile, where the remnants of the dielectric layer 14 are arranged, while the metallic layer 12 is exposed at the external surface 16 and the metallic layer 12 at the lower peaks of the sinusoidal wave profile, where the dielectric layer 14 has been totally removed. In other embodiments, the LIPSS 20 formed on the external surface 16 may have a wave profile other than a sinusoidal wave profile.

FIG. 6 shows an exemplary wave profile of the LIPSS 20 formed on the external surface 16 of an electrical connection pad 10′ according to embodiments of the present invention, illustrating the periodic variation in the thickness of the electrical connection pad 10′, i.e. in the metallic layer 12 and/or the dielectric layer 14 arranged on the metallic layer 12.

As a result of the laser treatment, the metallic layer 12 of the electrical connection pad 10′ of FIG. 5 now has a thickness H1′ that can be equal to or smaller than the thickness H1 of the metallic layer 12 before the laser treatment, depending on the particular settings of the laser treatment, and the dielectric layer 14 has a thickness H2′ that can be equal to or smaller than the thickness H2 of the dielectric layer 14 before the laser treatment, depending on the particular settings of the laser treatment.

In the example shown, the thickness H1′ of the metallic layer 12 after the laser treatment is about 30 μm and the thickness H2′ of the dielectric layer 14 after the laser treatment is about 3 nm. The LIPSS 20 has an amplitude modulation A and a period P. In the example shown in FIG. 5, the amplitude modulation is about 200 nm and the period is about 950 nm.

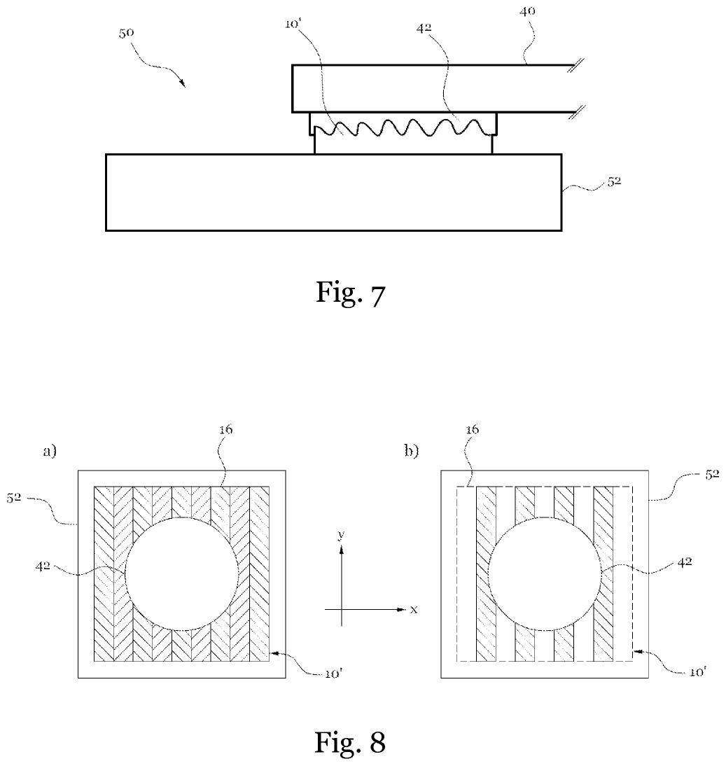

FIG. 7 shows a printed circuit board 50 according to an embodiment of the invention comprising an electrical connection pad 10′ acting as a solder pad to establish an electrical connection between a conductive substrate structure 52 of the printed circuit board 50 and a conductive wiring 40 via solder material 42, which may comprise lead, tin or any other suitable solder material. The solder material 42 may partially or completely cover the electrical connection pad 10′. Through the electrical connection pad 10′, a durable electrical connection between the conductive substrate structure 52 and another electronic component connected thereto through the conductive wiring 40 is formed, which thanks to the principles of the present invention is explained above, has an improved solderability due to the presence of a LIPSS and can be formed with a simplified manufacturing method in a workflow resulting in electrical connection pads having practically no caducity date or storage/transportation time limit before becoming useless.

FIG. 8 shows exemplary top views of electrical connection pads 10′ arranged on a substrate structure 52, after the electrical connection pad 10′ has been laser-treated. The solder material 42 is arranged on the electrical connection pad 10′ and, in the example shown, defines a circular profile partially covering the external surface 16 of the electrical connection pads 10′.

FIG. 8a illustrates an electrical connection pad in which the external surface 16 has been completely laser-treated, for example by using laser light with a spot size S to linearly scan the external surface 16 over a first direction, indicated as direction “y” in FIG. 8, at different positions along a second direction, indicated as direction “x” in FIG. 8. In FIG. 8a, said different positions are spaced apart from each other by a distance equal to or smaller than the spot size S, such that 100% of the external surface 16 is covered by the resulting LIPSS. The area of the external surface 16 covered by the LIPSS is indicated in FIG. 8 as lined areas.

FIG. 8b illustrates an electrical connection pad 10′ in which the external surface 16 has been partially laser-treated, for example by linearly scanning the external surface 16 over the direction “y” at different positions along the direction “x” mutually spaced apart by a distance greater than the spot size S. As a result, in FIG. 8b, about 50% of the external surface 16 is laser-treated and contains the resulting LIPSS, as illustrated in the figure by the lined areas, which in the example shown form stripes extending along the direction “y”.

Although preferred exemplary embodiments are shown and specified in detail in the drawings and the preceding specification, these should be viewed as purely exemplary and not as limiting the invention. It is noted in these regards that only the preferred exemplary embodiments are shown and specified and that all variations and modifications should be protected, which presently or in the future lie within the scope of protection of the invention as defined in the claims.

### LIST OF REFERENCE SIGNS

10 electrical connection pad (before laser treatment)
10′ electrical connection pad (after laser treatment)
12 metallic layer
14 dielectric layer
16 external surface
20 laser induced periodic surface structure
30 laser device
32 laser light
34 laser light deflection system
40 conductive wiring
42 solder material
50 circuit board
52 conductive substrate
H1 thickness of the metallic layer (before laser treatment)
H2 thickness of the dielectric layer (before laser treatment)
H1′ thickness of the metallic layer (after laser treatment)
H2′ thickness of the dielectric layer (after laser treatment)
P period of the laser induced periodic surface structure
A modulation amplitude of the laser induced periodic surface structure
θ incidence angle of the laser
x, y directions

What is claimed is:

1-22. (canceled)

23: An electrical connection pad for providing an electrical connection between electronic components, wherein the electrical connection pad comprises:
a metallic layer; and
a laser induced periodic surface structure formed on an external surface of the electrical connection pad and exposing the metallic layer.

24: The electrical connection pad of claim 1, wherein the laser induced periodic surface structure has a period from 100 nm to 10 μm.

25: The electrical connection pad of claim 1, wherein the laser induced periodic surface structure has a modulation amplitude from 10 nm to 100 μm.

26: The electrical connection pad of claim 1, wherein the metal layer has a thickness from 1 μm to 10 mm.

27: The electrical connection pad of claim 1, wherein the metal layer comprises copper, zinc, tin, lead, brass, platinum, gold, silver and/or aluminium or combinations, compounds and/or alloys thereof.

28: The electrical connection pad of one of claim 1, further comprising a dielectric layer arranged on the metallic layer, wherein the laser induced periodic surface structure is further formed in the dielectric layer.

29: The electrical connection pad of claim 6, wherein the dielectric layer comprises a metal oxide, carbon and/or an organic material.

30: The electrical connection pad of claim 7, wherein the dielectric layer is a metal oxide layer comprising copper oxide, zinc oxide, tin oxide, lead oxide, brass oxide, platinum oxide, gold oxide, silver oxide, and/or aluminium oxide.

31: The electrical connection pad of claim 6, wherein the dielectric layer has a thickness between 1 nm and 5 μm, preferably between 1 nm and 1 μm, more preferably between 5 nm and 30 nm.

32: The electrical connection pad of claim 1, wherein the electrical connection pad is a solder pad.

33: A circuit board comprising an electrical connection pad for providing an electrical connection between electronic components, wherein the electrical connection pad comprises:
a metallic layer; and
a laser induced periodic surface structure formed on an external surface of the electrical connection pad and exposing the metallic layer.

34: A method for laser-treating an electrical connection pad, wherein the electrical connection pad comprises:
a metallic layer; and
a dielectric layer arranged on the metallic layer forming an external surface of the electrical connection pad;
wherein the method comprises:
laser-treating the external surface with polarised ultrashort-pulse pulsed laser light, thereby forming a laser induced periodic surface structure exposing the metal layer.

35: The method of claim 12, wherein the external surface is laser-treated with laser light pulses having a pulse length from 30 fs to 100 ns.

36: The method of claim 12, wherein the external surface is laser-treated with laser light pulses having a wavelength from 193 nm to 10.6 μm.

37: The method of claim 12, wherein the laser light has a fluence from 0.01 J/cm2 to 10 J/cm².

38: The method of claim 12, wherein laser-treating the external surface comprises laser-treating from 10% to 90% of the external surface.

39: The method of claim 12, wherein laser-treating the external surface comprises scanning at least a part of the external surface with the laser light using a laser light deflection system.

40: The method of claim 12, wherein the laser light is configured such that a modulation amplitude of the laser induced periodic surface structure is equal to or greater than a thickness of the dielectric layer.

41: The method of claim 12, wherein laser-treating the external surface comprises completely removing the dielectric layer.

42: The method of claim 12, wherein the external surface is laser-treated with an incidence angle from 0° to 45°.
